(19) United States
(12) Patent Application Publication
(10) Pub. No.: US 2011/0062517 A1
(43) Pub. Date: Mar. 17, 2011

(54) SEMICONDUCTOR DEVICE AND METHOD OF MANUFACTURING THE SAME

(75) Inventor: Hiromichi YOSHINAGA, Oita (JP)

(73) Assignee: Kabushiki Kaisha Toshiba, Tokyo (JP)

(21) Appl. No.: 12/874,172

(22) Filed: Sep. 1, 2010

(30) Foreign Application Priority Data
Sep. 16, 2009 (JP) 2009-214865

(51) Int. Cl. H01L 29/78; H01L 21/336

(52) U.S. Cl. 257/337; 438/286; 257/E29.261; 257/E21.417

(57) ABSTRACT

According to one embodiment, a semiconductor device includes: a semiconductor substrate of a first conductivity type; a source region; a drain region of a second conductivity type; a gate electrode formed via a gate insulating film on the semiconductor substrate between the source region and the drain region; and a drift region of the second conductivity type formed adjacent to the drain region from the drain region to a lower part of the gate electrode. The upper surface of the gate electrode is formed such that the height of a side on the source region side of a stack of the gate electrode and the gate insulating film is larger than the height of a side on the drain region side of the stack.

### CROSS-REFERENCE TO RELATED APPLICATIONS

This application is based upon and claims the benefit of priority from the prior Japanese Patent Application No. 2009-214865, filed on Sep. 16, 2009; the entire contents of which are incorporated herein by reference.

### FIELD

Embodiments described herein relate generally to a semiconductor device and a method of manufacturing the same.

### BACKGROUND

A power device such as a power integrated circuit (IC) including a high withstanding voltage device having a metal-oxide-semiconductor (MOS) structure is widely used as a device for high voltage and high current. As a MOS used in the power device, a laterally diffused MOS (LDMOS) is known (see, for example, Japanese Patent Application Laid-Open No. 2006-202847). The LDMOS has structure explained below. As a substrate of the LDMOS, a substrate on which an N-type buried layer and an N-type semiconductor layer are stacked on a P-type silicon substrate is used. A P+ source region and an N+ source region are formed adjacent to each other on a surface of a region where a source of a P-type well, which is formed in the substrate, is formed. A source electrode is provided to extend over the surfaces of the P+ source region and the N+ source region. An N+ drain region is formed on the surface of the substrate in a region where a drain is formed. A drain electrode is provided on the surface of the N+ drain region. A gate electrode is arranged via a gate oxide film on a substrate surface between the source electrode and the drain electrode. An N-type drain region having N-type impurity concentration lower than that of the N+ drain region is formed from the N+ drain region on the substrate surface to a lower part on the N+ drain region side of the gate electrode.

In the LDMOS, the N-type drain region is formed to creep into a region under the gate electrode of the substrate. Such an N-type drain region can be formed by forming a resist pattern on a substrate, on which a gate electrode is formed such that a formation region of a drain region is opened, and ion-implanting N-type impurities such as P at a predetermined angle other than the right angle with respect to the substrate surface, i.e., from an oblique direction.

In the power device, it is a general practice to form two or more LDMOSs on the substrate rather than only one LDMOS. For example, Japanese Patent Application Laid-Open No. 2005-327827 proposes a power device having structure in which LDMOSs adjacent to each other share a drain region.

However, when impurities are ion-implanted from the oblique direction as explained above, the impurities are not implanted in some region (shadowing region) because of an implantation angle of the impurities or a shadowing effect of the resist and the gate electrode. For example, if the impurities are implanted in a state in which a distance between gate electrodes adjacent to each other is too small and an implantation angle of the impurities with respect to the substrate surface is small, the impurities are blocked by the gate electrodes and the resist and do not reach a substrate surface between the gate electrodes. Therefore, when the impurities are implanted from the oblique direction to form a diffusion layer without forming the shadowing region between the adjacent gate electrodes, the distance between the adjacent gate electrodes has to be set to equal to or larger than a predetermined distance. As a result, a reduction in size of a semiconductor device is hindered.

### BRIEF DESCRIPTION OF THE DRAWINGS

FIG. 1 is a schematic sectional view of an example of the structure of a semiconductor device according to a first embodiment;

FIGS. 2A to 2K are schematic sectional views of an example of a procedure of a method of manufacturing the semiconductor device according to the first embodiment; and

FIGS. 3A and 3B are schematic sectional views of the shape of a gate electrode according to a second embodiment.

### DETAILED DESCRIPTION

In general, according to one embodiment, a semiconductor device includes: a semiconductor substrate of a first conductivity type; a source region; a drain region of a second conductivity type formed away from the source region; a gate electrode formed via a gate insulating film on the semiconductor substrate between the source region and the drain region; a drift region of the second conductivity type formed adjacent to the drain region from the drain region to a lower part of the gate electrode; a source electrode connected to the source region; and a drain electrode connected to the drain region. The source region includes a first source region of the first conductivity type formed on the surface of the semiconductor substrate and a second source region of the second conductivity type formed adjacent to the first source region. The drift region has concentration lower than impurity concentration of the drain region. The upper surface of the gate electrode is formed such that the height of a side on the source region side of a stack of the gate electrode and the gate insulating film is larger than the height of a side on the drain region side of the stack.

Exemplary embodiments of a semiconductor device and a method of manufacturing the same will be explained below in detail with reference to the accompanying drawings. The present invention is not limited to the following embodiments. Sectional views of the semiconductor device referred to in the embodiments are schematic. A relation between the thickness and the width of a layer, a ratio of thicknesses of layers, and the like are different from actual ones. A film thickness explained below is an example. An actual film thickness is not limited to this.

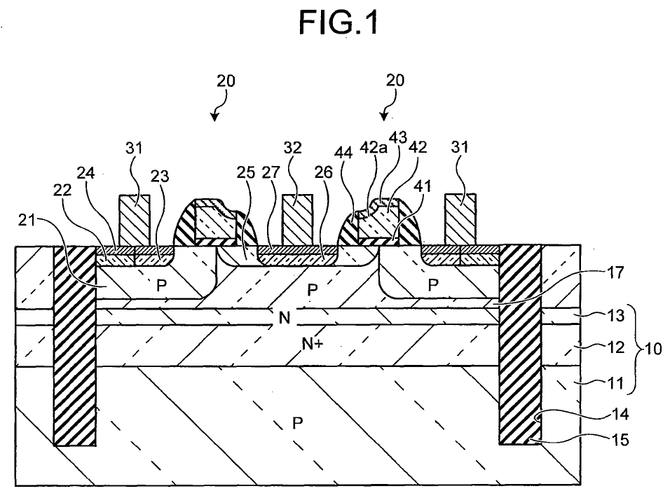

FIG. 1 is a schematic sectional view of an example of the structure of a semiconductor device according to a first embodiment. As a substrate 10, for example, a P-type silicon substrate 11 in which an N+ buried layer 12 is formed at predetermined height is used. The substrate 10 has structure in which, for example, on the P-type silicon substrate 11, the N+ buried layer 12 including a silicon layer implanted with N-type impurities and an N-type semiconductor layer 13 including a silicon layer having concentration of the N-type impurities lower than that of the N+ buried layer 12 are formed.

In predetermined regions of the substrate 10, deep trench 14 having predetermined depth reaching the silicon substrate 11 in a lower layer of the N+ buried layer 12 is formed in, for example, a frame shape in plan view. Silicon oxide film, silicon film, or the like is embedded in the deep trench 14 to form a deep trench film 15 serving as a device isolation film. A region sectioned by the deep trench film 15 is a device formation region.

A P-type well 17 is formed in the N-type semiconductor layer 13 at predetermined depth from the surface in the device formation region. Two LDMOSs 20 having source regions, gate electrodes, and drain regions are formed in a region between the deep trench films 15.

In predetermined positions of the P-type well 17, gate electrodes 42 including, for example, polysilicon films are provided via gate insulating films 41. Silicide films 43 are formed on the upper surfaces of the gate electrodes 42. Sidewalls 44 including silicon oxide films or silicon nitride films are provided on sides of the gate electrodes 42.

P-type base regions 21 are formed from places near lower centers of the gate electrodes 42 to the deep trench films 15. Source regions in which P+ source regions 22 and N+ source regions 23 are set in contact with each other are formed on the surfaces of the P-type base regions 21. Silicide films 24 are formed on the upper surfaces of the P+ source regions 22 and the N+ source regions 23. Source electrodes 31 are provided over the surfaces of the P+ source regions 22 and the surfaces of the N+ source regions 23.

On the surface of the N-type semiconductor layer 13 between the two gate electrodes 42, a drift layer 25 and a drain region 26 are formed. The drift layer 25 is formed near the surface of the P-type well 17 (the N-type semiconductor layer 13) extending from the place near the lower center of one gate electrode 42 to the place near the lower center of the other gate electrode 42. The drain region 26 is formed near the surface of the P-type well 17 (the N-type semiconductor layer 13) between the sidewalls 44 of the two gate electrodes 42 such that the drain region 26 has N-type impurity concentration higher than that of the drift layer 25. In this way, between the two gate electrodes 42, a plurality of N-type diffusion layers having different impurity concentrations are present in an arraying direction of the gate electrodes 42. A silicide film 27 is formed on the upper surface of the drain region 26. A drain electrode 32 is provided on the silicide film 27.

In this way, in the semiconductor device according to the first embodiment, the LDMOSs 20 adjacent each other share the drift layer 25, the drain region 26, and the drain electrode 32.

The structure of the gate electrode 42 according to the first embodiment is explained below. The height of a side on the source region side of the gate electrode 42 (hereinafter, “second side”) is set to be 1.05 times or more as large as the height of a side on the drain region 26 side (hereinafter, “first side”). In the example shown in FIG. 1, a slope of a curved surface shape and one step are provided on the upper surface of the gate electrode 42 such that the height of the first side is smaller than the height of the second side. When the height of the second side is less than 1.05 times as large as the height of the first side, an effect of reducing a shadowing region during formation of the drift layer 25 explained later decreases.

As explained later, when the drift layer 25 extending to a lower part of the gate electrode 42 is formed, ion implantation is performed from an oblique direction other than a direction perpendicular to the substrate surface. The slope and the step are provided to reduce the shadowing region in which the ion implantation in the oblique direction is blocked by the gate electrode 42 and a resist.

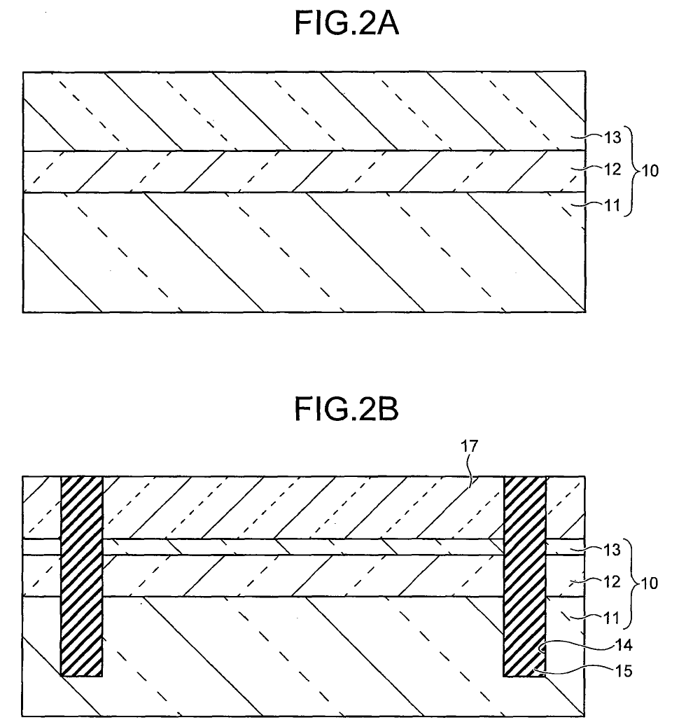

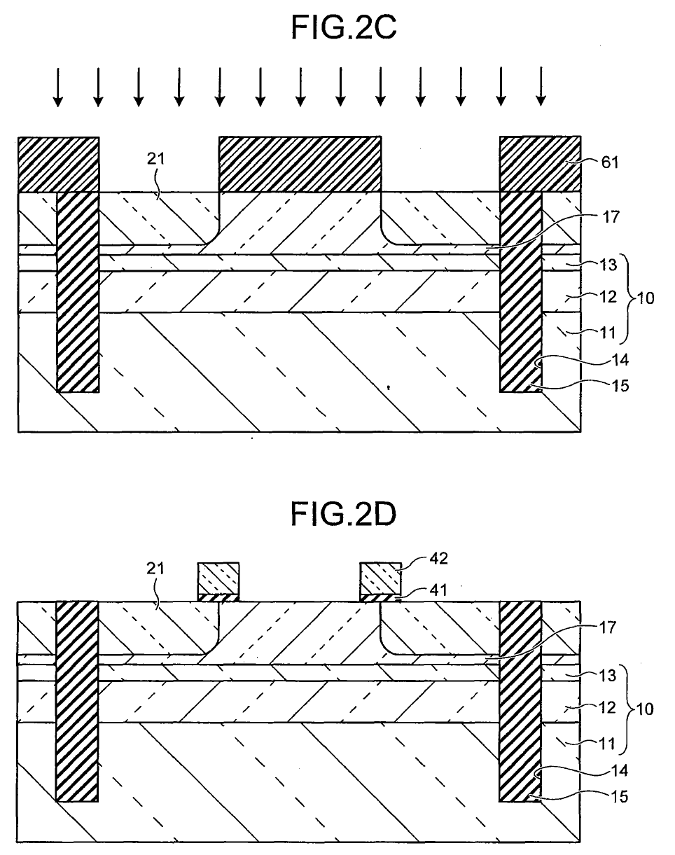

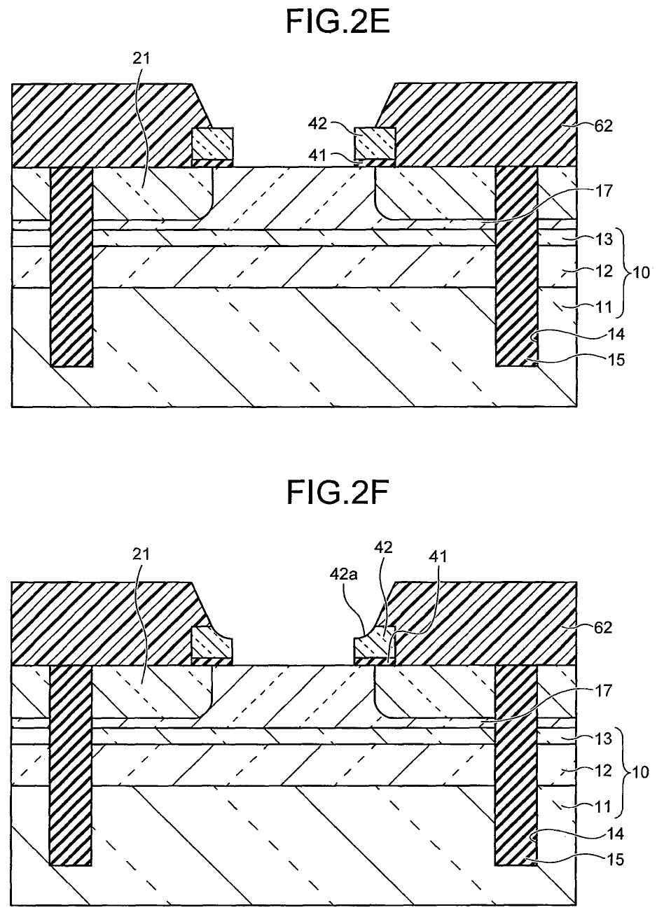

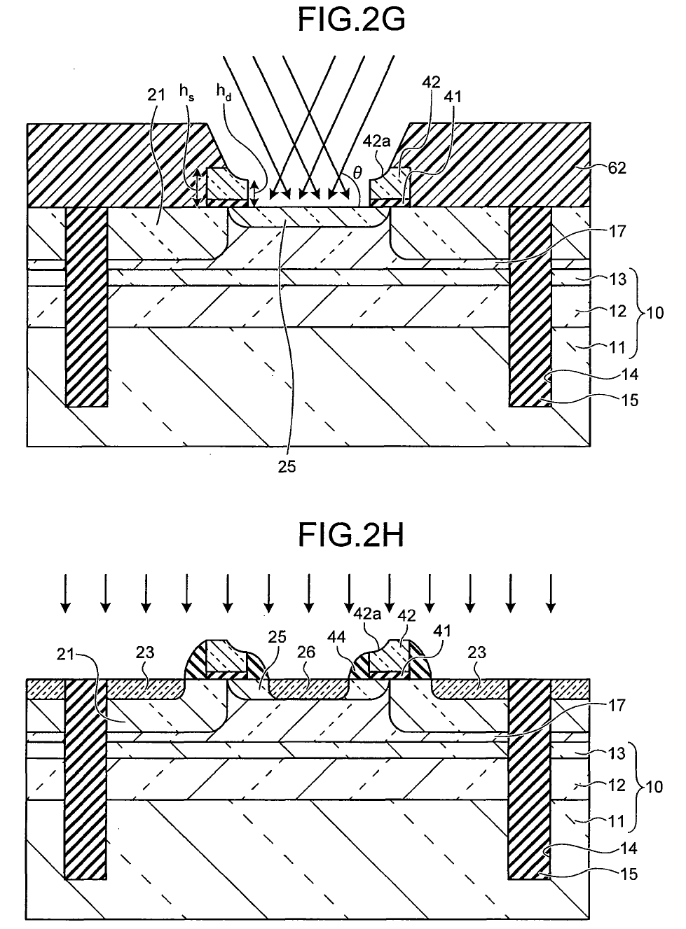

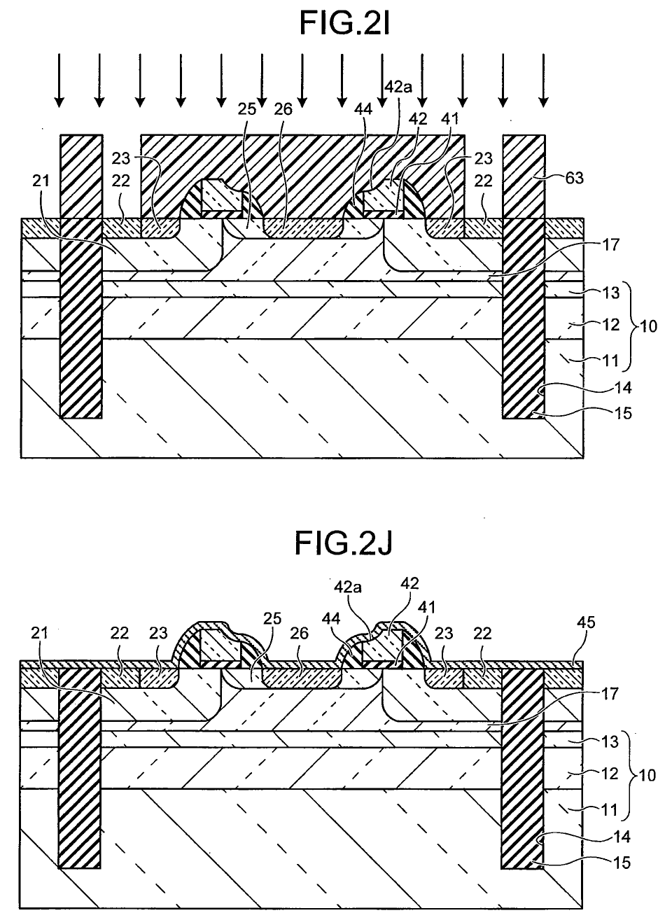

A method of manufacturing the semiconductor device having such structure is explained below. FIGS. 2A to 2K are schematic sectional views of an example of a procedure of a method of manufacturing the semiconductor device according to the first embodiment. First, as shown in FIG. 2A, as the substrate 10, the P-type silicon substrate 11 in which the N+ buried layer 12 is formed at depth of 5 micrometers from the surface of the substrate 10 is used. Specifically, the substrate 10 in which the N+ buried layer 12 and the N-type semiconductor layer 13 having thickness of 5 micrometers are formed in order on the P-type silicon substrate 11 is used.

Subsequently, as shown in FIG. 2B, in the substrate 10, the deep trench 14 is formed to be deeper than the lower surface of the N+ buried layer 12. After the deep trench film 15 is filled in the deep trench 14, the P-type well 17 is formed to predetermined depth from the surface of the N-type semiconductor layer 13.

For example, on the substrate 10, a stopper film including an SiN film having thickness of 200 nanometers is formed by the low pressure chemical vapor deposition (LPCVD) method and, then, an SiO mask film is formed by the CVD method. A resist is applied on the mask film and opening for forming the deep trench 14 is formed. Thereafter, a pattern formed on the resist is transferred onto the mask film. The substrate 10 is etched to a position deeper than the lower surface of the N+ buried layer 12 by a dry etching method such as the reactive ion etching (RIE) method with the mask film as a mask to form the deep trench 14. Thereafter, sidewalls of the deep trench 14 are oxidized, the insides of the deep trench 14 is filled with silicon oxide film or silicon film to form the deep trench film 15. A region sectioned by the deep trench film 15 is a device formation region. Thereafter, P-type impurities are implanted to a position shallower than the lower surface of the N-type semiconductor layer 13 from the surface of the N-type semiconductor layer 13 by the ion implantation method to form the P-type well 17.

Subsequently, as shown in FIG. 2C, a resist 61 is applied on the substrate 10 and patterned by a photolithography technique such that regions where the base regions 21 are formed are opened. Thereafter, ion implantation is performed from the direction perpendicular to the substrate surface to introduce P-type impurities such as B in a range of the depth of the P-type well 17. The P-type impurities are activated to form the base regions 21.

After the resist 61 is removed by a method such as resist stripping, an oxide film is formed on the substrate 10 by an oxidation technique. Thereafter, a polysilicon film is deposited by a method such as the LPCVD method. A resist is applied on the polysilicon film and patterned in a gate electrode shape by a lithography technique. Thereafter, the polysilicon film and the oxide film are etched by the dry etching method with a resist pattern as a mask. Consequently, as shown in FIG. 2D, stacks of the gate insulating films 41 and the gate electrodes 42 are formed on the device formation region. Two stacks of the gate insulating films 41 and the gate electrodes 42 are formed in the device formation region.

Subsequently, as shown in FIG. 2E, a resist 62 is applied over the entire surface on the substrate 10 on which the gate electrodes 42 are formed. The resist 62 is patterned by the lithography technique such that at least parts of regions on the base regions 21 side of the upper surfaces of the gate electrodes 42 are masked by the resist 62. The resist 62 is patterned such that the resist 62 formed on the upper surfaces of the gate electrodes 42 has a taper shape. A pattern having such a shape is formed by, for example, making an exposure condition proper such that tapers are formed in the resist 62 after exposure on the gate electrodes 42 or performing low temperature heat treatment after the exposure such that the tapers are formed in the resist 62 on the gate electrodes 42 when the resist pattern is formed.

Subsequently, as shown in FIG. 2F, etching of the gate electrodes 42 is performed by the dry etching method with the resist 62 as a mask. During the etching, the resist 62 is gradually reduced together with the exposed gate electrodes 42. However, because ends of the resist 62 formed on the upper surfaces of the gate electrodes 42 are formed in a taper shape, in portions where the resist 62 is thin, when the resist 62 is removed by the etching, the gate electrodes 42 under the resist 62 are etched. Consequently, steps 42a having curves only on one sides (the sides of the first sides) of the gate electrodes 42 are formed. Etching time is desirably adjusted such that the height on the sides of the second sides of the gate electrodes 42 is 1.05 times or more as large as the height on the sides of the first sides.

Thereafter, as shown in FIG. 2G, N-type impurities such as P are ion-implanted from a direction of an angle θ other than the right angle with respect to the substrate surface with the resist 62, which is used for processing the gate electrodes 42, and the gate electrodes 42, on the upper surfaces of which the steps 42a are formed, as masks. The drift layer 25 is formed from a place near the lower center of one gate electrode 42 to a place near the lower center of the other gate electrode 42. In the ion implantation from the oblique direction, the gate electrodes 42 having the small height on the sides of the first sides and the resist 62 having the slopes toward the sides of the first sides are used. Therefore, it is possible to reduce the shadowing region, in which impurity ions are blocked by the gate electrodes 42 and the resist 62, compared with a shadowing region formed by performing the ion implantation without reducing the height on the sides of the first sides of the gate electrodes 42 and without inclining the resist 62 on the sides of the first sides.

After removing the resist 62 by resist stripping, an insulating film such as a silicon oxide film is formed at thickness of, for example, 100 nanometers on the substrate 10, on which the gate electrodes 42 are formed, by a method such as the LPCVD method. Subsequently, etch-back is performed by the dry etching method to remove the insulating film formed on the substrate 10 and the gate electrodes 42 and leave the insulating film only on the sides of the stacks of the gate insulating films 41 and the gate electrodes 42. Consequently, as shown in FIG. 2H, the sidewalls 44 are formed on the sides of the stacks of the gate insulating films 41 and the gate electrodes 42. Thereafter, a region other than the device formation region is masked and the N-type impurities are ion-implanted in the device formation region from the direction perpendicular to the substrate surface. In the device formation region, the gate electrodes 42 and the sidewalls 44 serve as masks and a N-type diffusion layer is formed at predetermined depth from the surface of the substrate 10. Thereafter, the implanted N-type impurities are activated, whereby the N-type diffusion layer on the sides of the second sides of the gate electrodes 42 becomes to the N+ source regions 23 and the N-type diffusion layer on the sides of the first sides becomes to the drain region 26. As a result, the N-type diffusion layer having a concentration gradient in a lateral direction (a channel length direction), i.e., the drift layer 25 and the drain region 26 are formed right under a region between the two gate electrodes 42. The N-type impurities are also introduced into the gate electrodes 42. Therefore, the gate electrodes 42 become formed by N-type polysilicon and get to have conductivity.

Subsequently, as shown in FIG. 2I, a resist 63 is applied over the entire surface on the substrate 10. The resist 63 is patterned by the lithography technique such that formation regions of the P+ source regions 22 are opened. P-type impurities such as B are ion-implanted from the direction perpendicular to the substrate surface and activated, whereby the P+ source regions 22 are formed.

Subsequently, as shown in FIG. 2J, a metal film 45 including metal, which reacts with silicon to form silicide, is deposited over the entire surface on the substrate 10 by the LPCVD method. Examples of such metal includes W, Ti, Co, or Ni.

Thereafter, as shown in FIG. 2K, heat treatment is performed by rapid thermal annealing (RTA) to silicidize the upper surfaces of the P+ source regions 22, the N+ source regions 23, the drain region 26, and the gate electrodes 42 in a self-aligning manner. The un-reacting metal film is removed and the source electrodes 31 and the drain electrode 32 are respectively formed on source regions including the P+ source regions 22 and the N+ source regions 23 and the drain region 26, whereby the semiconductor device shown in FIG. 1 is obtained.

In the first embodiment, the resist 62 having the slope is formed on the upper surfaces of the gate electrodes 42 as a mask and etched to provide the step such that the height on the sides of the second sides is 1.05 times or more as large as the height on the sides of the first sides of the gate electrodes 42. Thereafter, impurities are ion-implanted from an angle θ with respect to the substrate surface. Consequently, there is an effect that it is possible to reduce a shadowing region in which the ion implantation from the oblique direction is blocked by the resist 62 and the gate electrodes 42.

For example, compared with a distance between the two gate electrodes 42 arranged not to form the shadowing region without providing the steps on the upper surfaces of the gate electrodes 42 or forming the resist 62 having the taper as explained above, in the first embodiment, the distance between the two gate electrodes 42 can be reduced by a distance x indicated by the following Formula (I). In FIG. 2G, the height of the second sides of the stacks of the gate insulating films 41 and the gate electrodes 42 is represented as hₛ, the height of the first sides is represented as h_{d}, and an angle of ion implantation is represented as θ.

X=2×|hₛ−h_{d}|/tan θ (1)

Specifically, compared with the method in which the steps are not provided in the upper parts of the gate electrodes 42 and the resist 62 is not processed into the taper shape, in the method of manufacturing the semiconductor device according to the first embodiment, the distance between the adjacent two gate electrodes 42 can be reduced by the distance x indicated by Formula (1). As a result, there is an effect that the size of chips of the semiconductor device can also be reduced, the number of chips formed from the same wafer is increased, and manufacturing cost for the semiconductor device can also be reduced.

For example, when the height hₛ of the second sides of the stacks of the gate insulating films 41 and the gate electrodes 42 is set to 200 nanometers, the height h_{d} of the first sides is set to 180 nanometers (hₛ/h_{d}=1.11), and the angle θ of the ion implantation is set to 45°, the distance between the two gate electrodes 42 can be reduced by x=40 nanometers according to Formula (I).

When a silicide film is formed on the upper surfaces of gate electrodes, to further reduce parasitic resistance, there is a method of increasing a dimension of the gate electrodes or changing a silicide material. However, the method of increasing a dimension of the gate electrodes has a problem in that the size of a semiconductor device increases and operation speed of a device decreases. The method of changing a silicide material has a problem in that a process needs to be changed and cost increases.

On the other hand, according to the first embodiment, because the steps 42a are formed on the gate electrodes 42, a surface area of the regions to be silicidized on the upper surfaces of the gate electrodes 42 increases. Therefore, a larger effect can be obtained for a reduction in resistance of the gate electrodes 42. In other words, it is possible to reduce parasitic resistance of the gate electrodes 42 without increasing a dimension of the gate electrodes 42 or changing a silicide material. As a result, there is also an effect that it is possible to manufacture a semiconductor device applicable to higher-speed operation compared with the past.

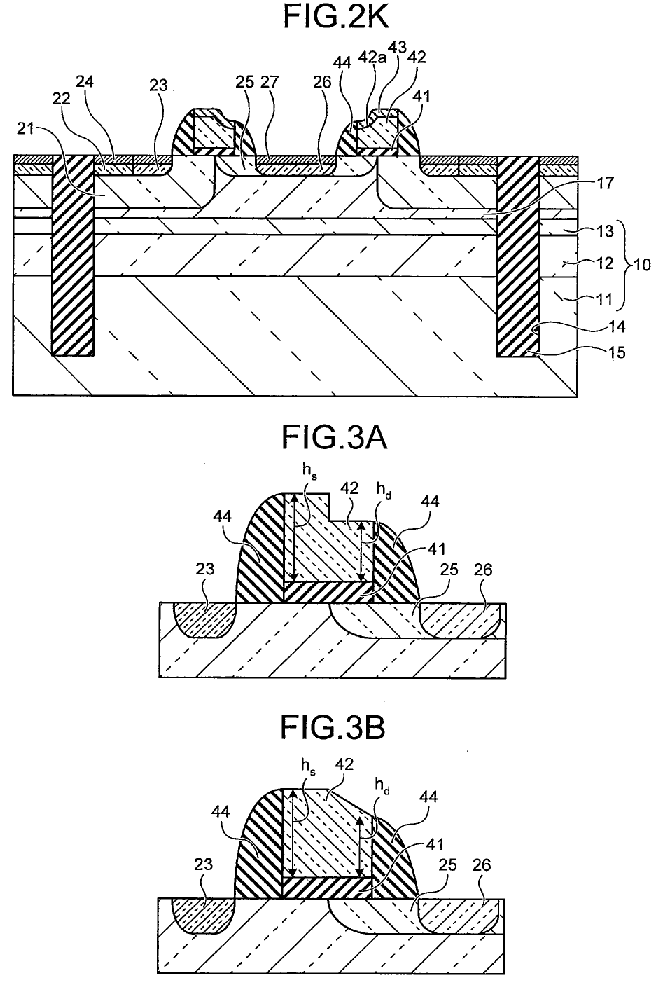

FIGS. 3A and 3B are schematic sectional views of the shape of a gate electrode according to a second embodiment. In FIG. 3A, the gate electrode 42 has a step with the height of the upper surface of the gate electrode 42 discontinuously changing near the center such that the height on the side of the first side is lower than the height of the second side. In FIG. 3B, the gate electrode 42 has inclined structure in which the height of the upper surface of the gate electrode 42 gradually decreases from the place near the center toward the side on the first side such that the height on the side of the first side is lower than the height of the second side. With the gate electrode 42 having the structure shown in FIG. 3, it is possible to obtain effects same as those in the first embodiment. Components same as those in the first embodiment are denoted by the same reference numerals and signs and explanation of the components is omitted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate of a first conductivity type;
a source region including a first source region of the first conductivity type formed on a surface of the semiconductor substrate and a second source region of a second conductivity type formed adjacent to the first source region;
a drain region of the second conductivity type formed away from the source region on the surface of the semiconductor substrate;
a gate electrode formed via a gate insulating film on the semiconductor substrate between the source region and the drain region;
a drift region of the second conductivity type formed adjacent to the drain region from the drain region to a lower part of the gate electrode, and having concentration lower than impurity concentration of the drain region;
a source electrode connected to the source region; and
a drain electrode connected to the drain region, wherein
an upper surface of the gate electrode is formed such that height of a side on the source region side of a stack of the gate electrode and the gate insulating film is larger than height of a side on the drain region side of the stack.

2. The semiconductor device according to claim 1, further comprising a device isolation insulating film reaching predetermined depth from a surface of a device formation region, in which the drain region, the gate electrode, and the source region are formed, and formed around the device formation region to separate the device formation region from a device formation region adjacent thereto.

3. The semiconductor device according to claim 1, wherein the gate electrode has an upper surface of a step shape, a slope shape, or a shape formed by combining the step shape and the slope shape such that height of a side on the source region side is large compared with height of a side on the drain region side.

4. The semiconductor device according to claim 1, wherein height of a side on the source region side of the gate electrode is 1.05 times or more as large as height of a side on the drain region side.

5. The semiconductor device according to claim 1, wherein
the semiconductor layer and the gate electrode are made of silicon, and
silicide layers are formed on upper surfaces of the gate electrode, the source region, and the drain region.

6. The semiconductor device according to claim 2, wherein
the semiconductor substrate has structure in which a buried layer of the second conductivity type and a semiconductor layer of the second conductivity type having predetermined thickness and having concentration of impurities of the second conductivity type lower than that of the buried layer are stacked on the semiconductor substrate of the first conductivity type, and
the semiconductor device further comprises:
a well of the first conductivity type formed at predetermined depth from the surface of the semiconductor layer in the device formation region; and
a base region of the first conductivity type including a formation position of the source region in the device formation region and formed shallower than thickness of the semiconductor layer.

7. The semiconductor device according to claim 2, wherein
a pair of the gate electrodes are arranged at a predetermined distance in the device formation region,
the drain region is formed on a surface of the semiconductor substrate between the pair of gate electrodes, and
the drift regions are formed adjacent to the drain region from the drain region to a lower part of each of the pair of gate electrodes.

8. A method of manufacturing a semiconductor device, comprising:
forming a gate electrode via a gate insulating film in a predetermined position on a semiconductor substrate of a first conductivity type;
applying a resist on the semiconductor substrate;
patterning the resist such that a part of an upper surface on a side of a first side of the gate electrode is exposed and an end of the resist formed on the upper surface of the gate electrode has a taper shape;
etching a part of the gate electrode with the resist as a mask such that the first side of the gate electrode is lower than a second side opposed to the first side;
ion-implanting impurities of a second conductivity type on a surface of the semiconductor substrate from an oblique direction with the resist and the gate electrode as masks to form a drift layer;
ion-implanting the impurities of the second conductivity type with the gate electrode as a mask to form a drain region in a predetermined region in the drift layer and form a second source region in a predetermined region on the surface of the semiconductor substrate; and
ion-implanting impurities of the first conductivity type in a predetermined region of the second source region to form a first source region.

9. The method of manufacturing a semiconductor device according to claim 8, wherein the patterning the resist includes performing exposure such that the resist after the exposure has a taper shape on the gate electrode.

10. The method of manufacturing a semiconductor device according to claim 8, wherein the patterning the resist includes performing low temperature heat treatment after exposure such that the resist after the exposure has a taper shape on the gate electrode.

11. The method of manufacturing a semiconductor device according to claim 8, wherein the etching the gate electrode includes controlling an etching time such that height of the second side is 1.05 times or more as large as height of the first side.

12. The method of manufacturing a semiconductor device according to claim 8, wherein the etching the gate electrode includes etching the gate electrode such that the gate electrode has an inclined structure in which height gradually decreases from a predetermined position on the upper surface of the gate electrode to the first side.

13. The method of manufacturing a semiconductor device according to claim 8, wherein the etching the gate electrode includes etching the gate electrode such that the gate electrode has, in a predetermined position on the upper surface of the gate electrode, a step with height of the upper surface of the gate electrode discontinuously changing.

14. The method of manufacturing a semiconductor device according to claim 8, wherein
the gate electrode includes a silicon layer, and
the method further comprises:
forming, after forming the second source region, a metal film including metal, which reacts with silicon to form silicide, on the substrate on which the gate electrode is formed; and
performing heat treatment to form silicide films on the gate electrode, on the first and second source region and, on the drain region.

15. The method of manufacturing a semiconductor device according to claim 14, wherein the metal film is formed of W, Ti, Co, or Ni.

16. A method of manufacturing a semiconductor device, comprising:
forming two stacks of gate insulating films and gate electrodes to be arranged in parallel on a semiconductor substrate of a first conductivity type;
applying a resist on the semiconductor substrate;
patterning the resist such that a part of an upper surface of a first side on the other gate electrode side of one gate electrode of the gate electrodes is exposed and an end of the resist formed on the upper surface of the one gate electrode have a taper shape;
etching a part of the one gate electrode with the resist as a mask such that the first side of the one gate electrode is lower than a second side opposed to the first side;
ion-implanting impurities of a second conductivity type on a surface of the semiconductor substrate from an oblique direction with the resist and the gate electrodes as masks to form a drift layer between the pair of gate electrodes;
ion-implanting the impurities of the second conductivity type with the gate electrodes as masks to form a drain region in a predetermined region in the drift layer and form a first source region in a predetermined region on the surface of the semiconductor substrate on a side of the second side of each of the gate electrodes; and
ion-implanting impurities of the first conductivity type in a predetermined region of the first source region to form a second source region.

17. The method of manufacturing a semiconductor device according to claim 16, wherein the etching the gate electrode includes controlling an etching time such that height of the second side is 1.05 times or more as large as height of the first side.

18. The method of manufacturing a semiconductor device according to claim 16, wherein
the gate electrode includes a silicon layer, and
the method further comprises:
forming, after forming the second source region, a metal film including metal, which reacts with silicon to form silicide, on the substrate on which the gate electrode is formed; and
performing heat treatment to form silicide films on the gate electrode, on the first and second source region and, on the drain region.

19. The method of manufacturing a semiconductor device according to claim 18, wherein the metal film is formed of W, Ti, Co, or Ni.

20. The method of manufacturing a semiconductor device, according to claim 16, wherein the etching the gate electrode includes etching the gate electrode such that the gate electrode has an inclined structure in which height gradually decreases from a predetermined position on the upper surface of the gate electrode to the first side.
